(19) United States
(12) Patent Application Publication
(10) Pub. No.: US 2016/0189989 A1
(43) Pub. Date: Jun. 30, 2016

(54) PROCESSING APPARATUS

(71) Applicant: DISCO CORPORATION, Tokyo (JP)

(72) Inventors: Satoshi Hanajima, Tokyo (JP); Shinya Yasuda, Tokyo (JP); Makoto Tanaka, Tokyo (JP); Harunobu Yuzawa, Tokyo (JP)

(21) Appl. No.: 14/970,842

(22) Filed: Dec. 16, 2015

(30) Foreign Application Priority Data
Dec. 24, 2014 (JP) 2014-260143

(51) Int. Cl. H01L 21/67; B28D 5/02

(52) U.S. Cl. CPC H01L 21/67092; B28D 5/022; H01L 21/67253

(57) ABSTRACT

A processing apparatus including a chuck table for holding a workpiece, a processing unit for processing the workpiece held on the chuck table, a feeding unit for relatively feeding the chuck table and the processing unit, and an imaging unit for imaging the result of processing of the workpiece by the processing unit. The imaging unit includes an illuminating portion for illuminating a work area of the workpiece after the processing and an imaging portion for imaging the work area after the processing. The illuminating portion has an illumination direction selecting function for selecting an illumination direction in illuminating the work area from any one of the east, west, north, and south positions with respect to the work area.

### BACKGROUND OF THE INVENTION

1. Field of the Invention

The present invention relates to a processing apparatus for performing predetermined processing to a workpiece.

2. Description of the Related Art

A plurality of devices such as ICs and LSIs are formed on the front side of a wafer so as to be separated by a plurality of division lines. The wafer thus having the devices is divided along the division lines into individual device chips by using a dicing apparatus, for example. The device chips are used in various electrical equipment such as mobile phones and personal computers. The dicing apparatus includes a chuck table for holding the wafer, cutting means having a rotatable cutting blade for cutting the wafer held on the chuck table, feeding means for relatively feeding the chuck table and the cutting means, and imaging means for detecting a work area of the wafer to be processed. In the dicing apparatus, the wafer can be cut along each division line by the cutting blade, thereby dividing the wafer into the individual device chips with high accuracy.

Further, in dividing the wafer by using the dicing apparatus, there is a possibility that chipping or dulling of the cutting blade may occur to cause a deterioration of the cut condition. To cope with this problem, the wafer is positioned directly below the imaging means during or after the cutting operation to image a cut groove formed on the wafer and check the condition of the cut groove (see Japanese Patent Laid-Open No. 2001-298000, for example).

### SUMMARY OF THE INVENTION

However, although the cut groove is imaged by using the imaging means, there is a problem that the contrast between the cut groove and its surroundings may low, so that the condition of the cut groove cannot be checked. Such a problem may also occur in the case that an ablated groove as a division start point is formed along each division line on the wafer by using a laser processing apparatus and this ablated groove is then checked.

It is therefore an object of the present invention to provide a processing apparatus which can facilitate reliable checking of the condition of a groove formed on the wafer as the result of processing.

In accordance with an aspect of the present invention, there is provided a processing apparatus including a chuck table for holding a workpiece; processing means for processing the workpiece held on the chuck table; feeding means for relatively feeding the chuck table and the processing means; and imaging means for imaging a result of processing of the workpiece by the processing means; the imaging means including an illuminating portion for illuminating a work area of the workpiece after the processing and an imaging portion for imaging the work area after the processing; the illuminating portion having an illumination direction selecting function for selecting an illumination direction in illuminating the work area from any one of east, west, north, and south positions with respect to the work area.

Preferably, the processing means includes cutting means having a rotatable cutting blade for cutting the workpiece. Preferably, when direction of extension of a cut groove formed on the workpiece by the cutting means coincides with east-west direction, the illumination direction selecting function is operated to illuminate the cut groove from either the east or west position or both the east and west positions.

As described above, the processing apparatus of the present invention includes the imaging means having the illuminating portion for illuminating the work area of the workpiece and the imaging portion for imaging the work area of the workpiece. The illuminating portion includes the illumination direction selecting function for selecting an illumination direction in illuminating the work area from any one of the east, west, north, and south positions with respect to the work area. Accordingly, the illumination direction can be selected so as to improve the contrast between the cut groove and its surroundings, and the cut groove can be imaged by the imaging portion as illuminating the cut groove in this illumination direction selected above. Accordingly, the condition of the cut groove can be reliably checked.

In the case that the processing apparatus of the present invention includes the cutting means and that the direction of extension of the cut groove formed on the workpiece by the cutting means coincides with the east-west direction, the illumination direction selecting function is operated to illuminate the cut groove from either the east or west position or both the east and west positions, so that the cut groove is illuminated along its longitudinal direction. Accordingly, the cut groove can be clearly imaged by the imaging portion.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a processing apparatus according to a preferred embodiment of the present invention;

FIG. 2 is a perspective view showing a configuration of imaging means;

FIG. 3 is a perspective view showing a condition where a workpiece is being cut by cutting means;

FIG. 4 is a perspective view showing a condition where a cut groove formed on the workpiece by the cutting means is being imaged by the imaging means; and

FIG. 5 is an elevational view showing a screen of a monitor displaying the condition of the cut groove imaged by the imaging means.

### DETAILED DESCRIPTION OF THE PREFERRED EMBODIMENT

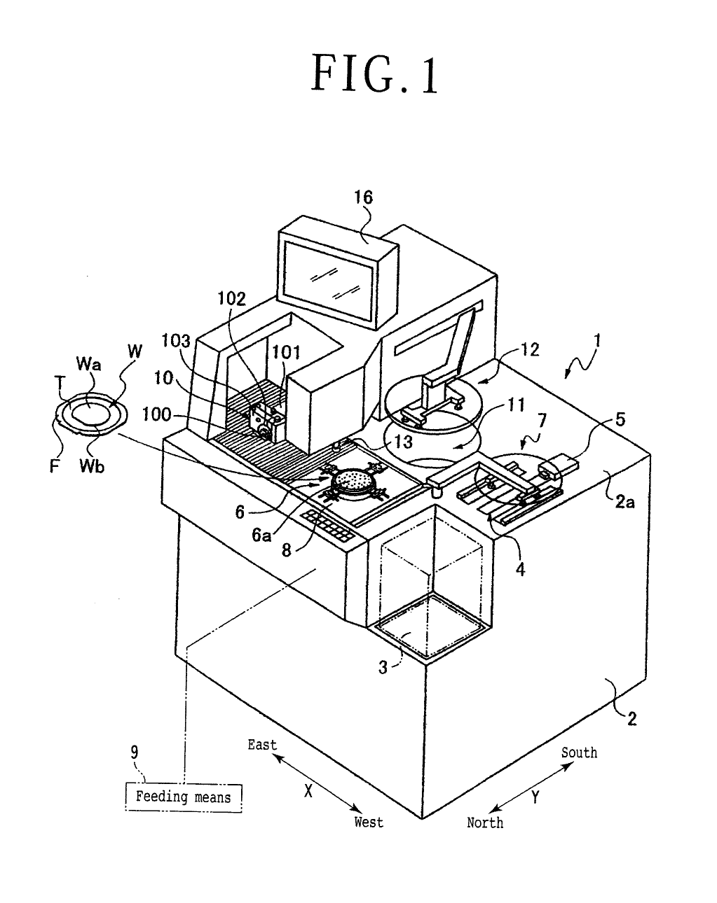

Referring to FIG. 1, there is shown a processing apparatus 1 according to a preferred embodiment of the present invention. The processing apparatus 1 is a cutting apparatus for cutting a workpiece into individual device chips. The processing apparatus 1 has a base housing 2. A cassette 3 for storing a plurality of workpieces is provided on the base housing 2 at a front portion thereof. The base housing 2 has an upper surface 2a, on which there are provided a temporary placement area 4 where the workpiece is temporarily placed, handling means 5 for taking the workpiece out of the cassette 3 before cutting and storing the workpiece into the cassette 3 after cutting, a chuck table 6 for holding the workpiece, and first transfer means 7 for transferring the workpiece from the temporary placement area 4 to the chuck table 6.

The chuck table 6 has a suction holding portion 6a for holding the workpiece under suction. The suction holding portion 6a is connected to a vacuum source (not shown). The chuck table 6 is surrounded by a cover member 8. The base housing 2 contains feeding means 9 for feeding the chuck table 6 in the X direction (east-west direction) shown by a double-headed arrow X in FIG. 1. When the feeding means 9 is operated, the chuck table 6 and the cover member 8 are moved together reciprocatively in the X direction.

There is provided on one side (east side) of the base housing 2 in the X direction cutting means 10 for cutting the workpiece held on the chuck table 6. The cutting means 10 essentially includes a spindle 100 having an axis extending in the Y direction (north-south direction) shown by a double-headed arrow Y in FIG. 1, which is perpendicular to the X direction, a spindle housing 101 for rotatably supporting the spindle 100 so as to surround the spindle 100, a cutting blade 102 mounted on the front end of the spindle 100, and a blade cover 103 for covering the cutting blade 102. The cutting means 10 performs a cutting operation in such a manner that the spindle 100 is rotated by a motor (not shown) to rotate the cutting blade 102, and the cutting blade 102 being rotated in fed to cut the workpiece.

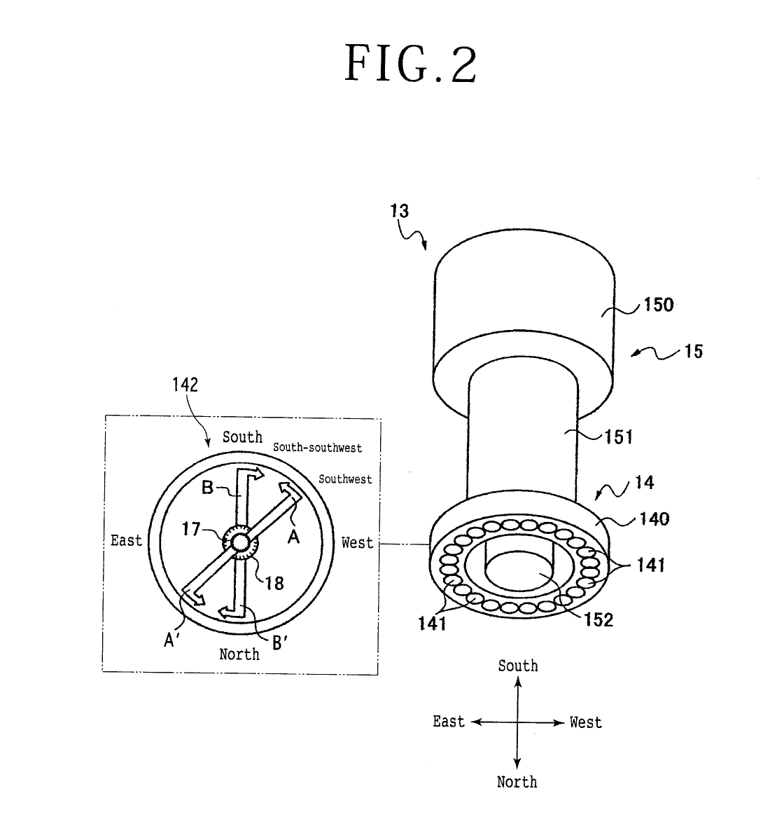

There are provided at the center of the base housing 2 a cleaning area 11 where the workpiece is cleaned after cutting and second transfer means 12 for transferring the workpiece from the chuck table 6 to the cleaning area 11 after cutting. Further, imaging means 13 for imaging the result of processing of the workpiece cut by the cutting means 10 is provided above the path of movement of the chuck table 6. As shown in FIG. 2, the imaging means 13 includes an illuminating portion 14 for illuminating a work area of the workpiece after cutting and an imaging portion 15 connected to the illuminating portion 14 for imaging the work area of the workpiece after cutting.

The imaging portion 15 essentially includes a CCD camera 150 for imaging the work area of the workpiece, a microscope 151, and an objective lens 152 mounted on the microscope 151. The imaging portion 15 functions also as an alignment portion for detecting the work area of the workpiece before cutting. The illuminating portion 14 essentially includes an annular base 140, a plurality of LEDs 141 provided on the lower surface of the annular base 140 so as to be arranged annularly around the objective lens 152, and an illumination direction selecting portion (illumination direction selecting function) 142 for selecting an optimum one of the LEDs 141 in illuminating the work area of the workpiece after cutting from any one of the east, west, north, and south positions with respect to the work area.

The illumination direction selecting portion 142 includes two shafts 17 and 18, two arrows A and A′ rotating about the shaft 17, and two arrows B and B′ rotating about the shaft 18. These four arrows A, A′, B, and B′ are independently rotatable. According to the positions of the four arrows A, A′, B, and B′, a control circuit (not shown) operates to turn on the LEDs 141 located between the arrow A and the arrow B and the LEDs 141 located between the arrow A′ and the arrow B′. For example, in the case that a cut groove formed on the workpiece is intended to be illuminated by the LEDs 141 from the south-southwest position and the north-northeast position, the operator adjusts the position of the arrow A to the southwest position and adjusts the position of the arrow B to the south position. Further, the operator adjusts the position of the arrow A′ to the northeast position and adjusts the position of the arrow B′ to the north position. In this manner, the LED 141 present at the south-southwest position between the arrow A and the arrow B and the LED 141 present at the north-northeast position between the arrow A′ and the arrow B′ are selected as an optimum illumination element, and the LEDs 141 present at the south-southwest position and the north-northeast position are turned on. The other LEDs 141 are turned off. In the case that the space between the arrow A and the arrow B is increased and the space between the arrow A′ and the arrow B′ is increased, the LEDs 141 to be turned on can be increased in number. Conversely, in the case that the space between the arrow A and the arrow B is decreased and the space between the arrow A′ and the arrow B′ is decreased, the LEDs 141 to be turned on can be decreased in number. The illumination direction selecting portion 142 is provided on the processing apparatus 1 shown in FIG. 1 at any arbitrary position where the operator can easily operate. As a modification, each LED 141 may be provided with a switch, wherein this switch is operated to turn on the LED 141 at a desired position.

Referring back to FIG. 1, the processing apparatus 1 further includes a monitor 16 for displaying an image obtained by the imaging means 13. The operator can check the processed condition of the workpiece according to the image displayed on the monitor 16.

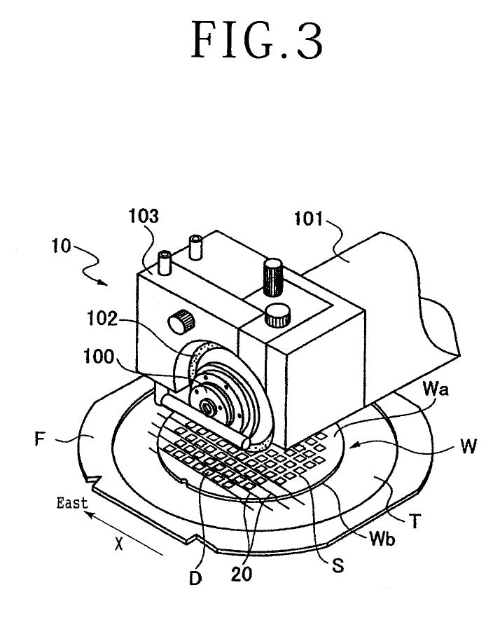

The operation of the processing apparatus 1 will now be described. In FIG. 1, reference symbol W denotes a wafer as a kind of workpiece. The material etc. of the wafer W is not especially limited. The wafer W has a front side Wa and a back side Wb. As shown in FIG. 3, a plurality of crossing division lines S are formed on the front side Wa of the wafer W to thereby define a plurality of separate regions where a plurality of devices D are individually formed. In cutting the wafer W, the back side Wb of the wafer W is preliminarily attached to a tape T supported to an annular frame F. A plurality of such wafers W are stored in the cassette 3 in the condition where each wafer W is supported through the tape T to the annular frame F.

One of the plural wafers W is taken out of the cassette 3 and then temporarily set in the temporary placement area 4 by the handling means 5. Thereafter, the wafer W is transferred from the temporary placement area 4 to the chuck table 6 and then placed on the suction holding portion 6a of the chuck table 6 by the first transfer means 7. Thereafter, the vacuum source (not shown) is operated to apply a suction force to the suction holding portion 6a of the chuck table 6, thereby holding the wafer W on the suction holding portion 6a under suction. Thereafter, the feeding means 9 is operated to move the chuck table 6 holding the wafer W under suction in the east direction (toward the east), thereby moving the wafer W to the position below the imaging means 13. At this position, the front side Wa of the wafer W is imaged by the imaging means 13 to thereby detect the division lines S to be cut. In detecting the division lines S, the LEDs 141 of the illuminating portion 14 constituting the imaging means 13 shown in FIG. 2 are turned on to illuminate the front side Wa of the wafer W. At this time, by superimposing all of the arrows A, A′, B, and B′, all of the LEDs 141 can be turned on to apply the light to the division lines S in all the directions (in 360 degrees), so that the division lines S can be clearly imaged and therefore smoothly detected.

Thereafter, cutting of the wafer W is performed by the cutting means 10. More specifically, the feeding means 9 shown in FIG. 1 is operated again to further move the chuck table 6 to the position below the cutting means 10. At this position, the chuck table 6 holding the wafer W is fed in the east direction (toward the east) by the feeding means 9, and at the same time the cutting blade 102 is rotated and lowered to cut the front side Wa of the wafer W. In this manner, the chuck table 6 and the cutting means 10 are relatively moved in the X direction as rotating the cutting blade 102 to thereby cut the wafer W along a predetermined one of the division lines S. As a result, a cut groove 20 extending in the X direction (the east-west direction) is formed along the predetermined division line S. Thereafter, the cutting means 10 is indexed in the Y direction to repeat the cutting operation by the cutting blade 102 along all of the other division lines S extending in the east-west direction, thereby sequentially forming similar cut grooves 20 along all of the other division lines S extending in the east-west direction.

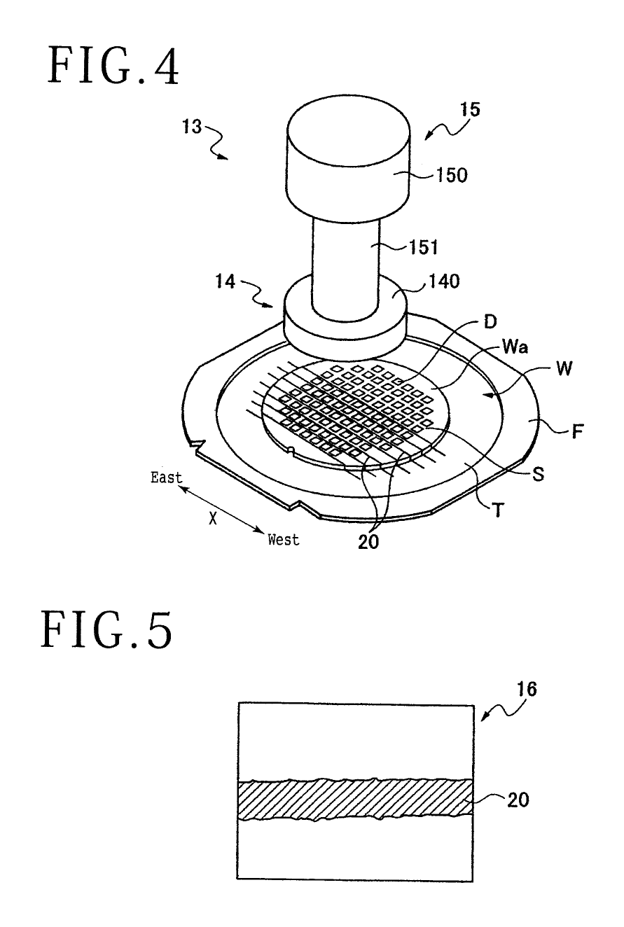

With any suitable timing, for example, just after finishing the cutting along all the division lines S extending in the east-west direction, the result of cutting of the wafer W is imaged by using the imaging means 13 to check the condition of each cut groove 20 formed on the wafer W as shown in FIG. 4. First, the feeding means 9 shown in FIG. 1 is operated to move the chuck table 6 in the west direction (toward the west), thereby moving the wafer W to the position directly below the imaging means 13.

As shown in FIG. 4, the direction of extension of each cut groove 20 formed on the wafer W coincides with the east-west direction. Accordingly, the illumination direction selecting portion 142 shown in FIG. 2 is operated to select the LED or LEDs 141 present at either the east or west position or both the east and west positions and then illuminate each cut groove 20 in the east-west direction. For example, in the case that the light is applied from both the east and west positions, the arrow A is set to the east-southeast position, the arrow B is set to the east-northeast position, the arrow A′ is set to the west-northwest position, and the arrow B′ is set to the west-southwest position. In the case that the light is applied from only the east position, the arrows A and A′ are set to the east-southeast position and the arrows B and B′ are set to the east-northeast position. The cut groove 20 illuminated by the LED or LEDs 141 is imaged by the imaging portion 15. In the case that the cut groove 20 is illuminated from both the east and west positions by the LEDs 141, the cut groove 20 can be imaged clearly as compared with the case that the cut groove 20 is illuminated from either the east or west position by the LED 141.

As shown in FIG. 5, the image obtained by the imaging portion 15 is displayed on the monitor 16 in the condition where the contrast between the cut groove 20 and its surroundings is improved. Accordingly, the operator can check whether the cut groove 20 is in a desired condition. In the case that the operator determines that any failure of the cutting blade 102 such as chipping and dulling has occurred after checking the cut condition of the cut groove 20, the cutting blade 102 is replaced by a new one. On the other hand, when the operator determines that the cut condition is good, the cutting blade 102 is not replaced by a new one, but it continues to be used. Since the imaging means 13 includes the illuminating portion 14, the contrast between the cut groove 20 and its surroundings can be improved in the image obtained by the imaging means 13, so that the cut condition can be reliably checked.

The configuration of the illuminating portion 14 is not limited to that shown in FIG. 2. For example, in the condition where the plural LEDs 141 are annularly arranged at the lower portion of the base 140 so as to surround the objective lens 152, a mask having an opening may be provided below the LEDs 141. In this configuration, the mask is rotated to align the opening of the mask with the LED 141 present at a desired one of the east, west, north, and south positions, so that the light from the LED 141 aligned with the opening of the mask is allowed to pass and the light from the other LEDs 141 is blocked. Accordingly, the cut groove can be illuminated by only the LED 141 present at the desired position. In this case, the rotatable mask has an illumination direction selecting function.

While the LEDs 141 are annularly arranged at the lower portion of the base 140 along the whole circumference thereof in the preferred embodiment described above, the base 140 may be made rotatable and the LED or LEDs 141 may be provided at a part of the lower portion of the base 140. For example, the LEDs 141 may be provided at both the east and west positions by rotating the base 140, or the LED 141 may be provided at either the east or west position by rotating the base 140. In such a configuration, the LED 141 may be set at any desired one of the east, west, north, and south positions by rotating the base 140. In this case, the rotatable base 140 has an illumination direction selecting function.

Further, the processing apparatus according to the present invention includes not only the processing apparatus 1 as a cutting apparatus for cutting the workpiece in the preferred embodiment, but also a laser processing apparatus for performing laser processing (ablation) to form an ablated groove on the workpiece, wherein the ablated groove is imaged to check the condition of the ablated groove.

As described above, the processing apparatus 1 according to the present invention includes the imaging means 13 having the illuminating portion 14 for illuminating the work area of the workpiece and the imaging portion 15 for imaging the work area of the workpiece. The illuminating portion 14 includes the illumination direction selecting portion 142 for selecting the LED 141 optimum in illuminating the work area of the workpiece from any one of the east, west, north, and south positions with respect to the work area. Accordingly, the LED 141 present at any one of the east, west, north, and south positions can be selected so as to improve the contrast between the cut groove 20 and its surroundings, and the cut groove 20 can be imaged by the imaging portion 15 as applying the light from this selected LED 141 to the cut groove 20. Accordingly, the image of the cut groove 20 can be clearly displayed on the monitor 16 included in the processing apparatus 1, so that the condition of the cut groove 20 can be easily checked.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing apparatus comprising:
a chuck table for holding a workpiece;
processing means for processing said workpiece held on said chuck table;
feeding means for relatively feeding said chuck table and said processing means; and
imaging means for imaging a result of processing of said workpiece by said processing means;
said imaging means including an illuminating portion for illuminating a work area of said workpiece after said processing and an imaging portion for imaging said work area after said processing;
said illuminating portion having an illumination direction selecting function for selecting an illumination direction in illuminating said work area from any one of east, west, north, and south positions with respect to said work area.

2. The processing apparatus according to claim 1, wherein said processing means includes cutting means having a rotatable cutting blade for cutting said workpiece.

3. The processing apparatus according to claim 2, wherein when direction of extension of a cut groove formed on said workpiece by said cutting means coincides with east-west direction, said illumination direction selecting function is operated to illuminate said cut groove from either the east or west position or both the east and west positions.
